(19) United States
(12) Patent Application Publication
(10) Pub. No.: US 2019/0089096 A1
(43) Pub. Date: Mar. 21, 2019

(54) ELECTRICAL CONNECTOR FOR REDUCING CROSSTALK

(71) Applicant: Dongguan Leader Precision Industry Co., Ltd., Qingxi Town (CN)

(72) Inventors: Wei-Chang LIEN, Qingxi Town (CN); Timothy T. PAK, Qingxi Town (CN)

(73) Assignee: Dongguan Leader Precision Industry Co., Ltd., Qingxi Town (CN)

(21) Appl. No.: 16/132,814

(22) Filed: Sep. 17, 2018

(30) Foreign Application Priority Data
Sep. 19, 2017 (CN) 201710844079.X
Sep. 19, 2017 (CN) 201710844096.3

(51) Int. Cl. H01R 13/6461; H01R 24/64; H01R 12/71; H05K 1/02

(52) U.S. Cl. CPC H01R 13/6461; H05K 1/0216; H01R 12/716; H01R 24/64

(57) ABSTRACT

Provided is an electrical connector. The electrical connector includes a circuit board defining a first surface and a second surface opposite to the first surface; a pair of first differential terminals; a pair of second differential terminals. Each terminal of the first and second differential terminals includes a contacting portion for mating with a mating electrical connector, a leg portion and a connecting portion connecting with the contacting portion and the leg portion. The contacting portions of the first and the second differential terminals are arranged in a same row, the leg portions of the first differential terminals are mounted on the first surface of the circuit board while the leg portions of the second differential terminals are mounted on the second surface of the circuit board.

### CROSS-REFERENCE TO RELATED APPLICATIONS

This application claims priority to Chinese patent application No. 201710844096.3 filed on Sep. 19, 2017 and Chinese patent application No. 201710844079.X filed on Sep. 19, 2017, the disclosures of which are incorporated herein by reference in their entireties.

### TECHNICAL FIELD

The present disclosure relates to an electrical connector, and more particularly to an electrical connector mounted on a circuit board.

### DESCRIPTION OF THE RELATED ART

U.S. Pat. No. 6,994,594 and China Utility No. 202585864U disclose an improved RJ 45 connector, which has two types of differential terminal pairs. The electrical currents flow in opposite orientations along the differential terminal pairs after the contacting portions of the terminal pairs are designed extending in opposite directions, thereby reducing crosstalk produced between different pairs of differential terminals.

As known, the higher speed of signal transmission, the more crosstalk is produced, even more productive design is desired to overcome such electrical magnetic interference issue in a connector with a higher and higher signal transmission.

### SUMMARY

Accordingly, the object of the present disclosure is to provide an electrical connector comprises a circuit board defining a first surface and a second surface opposite to the first surface; a pair of first differential terminals; a pair of second differential terminals. Each terminal comprises a contacting portion for mating with a mating electrical connector, a leg portion and a connecting portion connecting with the contacting portion and the leg portion. The contacting portions of the first and the second differential terminals are arranged in a same row, the leg portions of the first differential terminals are mounted on the first surface of the circuit board while the leg portions of the second differential terminals are mounted on the second surface of the circuit board.

Other objects, advantages and novel features of the disclosure will become more apparent from the following detailed description when taken in conjunction with the accompanying drawings.

### BRIEF DESCRIPTION OF THE DRAWINGS

The foregoing summary, as well as the following detailed description of the embodiments of the present disclosure, will be better understood when read in conjunction with the appended drawings. For the purpose of illustrating the disclosure, there are shown in the drawings embodiments which are presently preferred. As should be understood, however, the disclosure is not limited to the precise arrangements and instrumentalities shown. In the drawings:

FIG. 1 is a top perspective view of an electrical connector made in accordance with the present disclosure;

FIG. 2 is a side view of the electrical connector shown in FIG. 1;

FIG. 3 is a perspective view of the electrical connector shown in FIG. 1;

FIG. 4 is a perspective view of the terminals of another embodiment made in accordance with the present disclosure;

FIG. 5 is a side view of the electrical connector shown in FIG. 4;

FIG. 6 is a top perspective view of the electrical connector of another embodiment made in accordance with the present disclosure, wherein a retaining block is added;

FIG. 7 is a bottom perspective view of the electrical connector shown in FIG. 6;

FIG. 8 is a perspective view of a RJ 45 connector in which the electrical connector is assembled;

FIG. 9 is an exploded perspective view of the RJ 45 connector shown in FIG. 8;

FIG. 10 is a perspective view of a circuit board of another embodiment made in accordance with the present disclosure;

FIG. 11 is a perspective view of the shielding plate shown in FIG. 10;

FIG. 12 is an exploded perspective view of the shielding plate shown in FIG. 11;

FIG. 13 is a side view of the electrical connector; and

FIG. 14 is a cross sectional view of the circuit board.

### DETAILED DESCRIPTION

Reference will now be made in detail to the embodiment of the present disclosure.

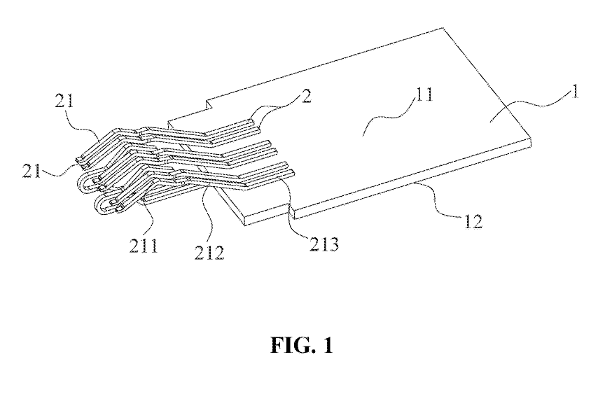

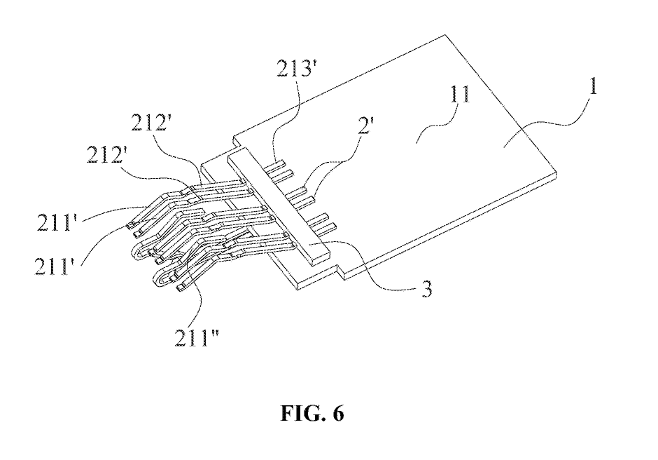

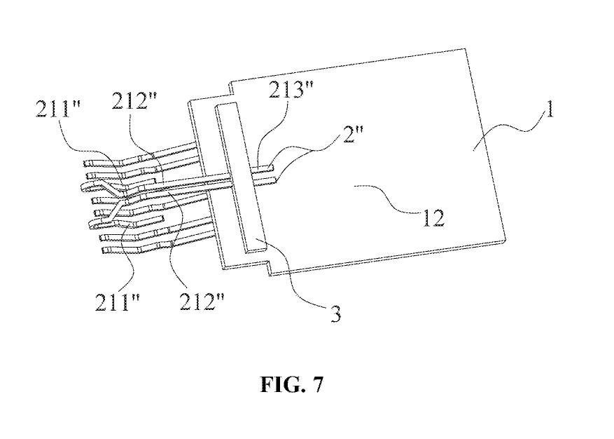

As shown in FIGS. 1 through 3, an electrical connector of an embodiment of this present disclosure includes a circuit board 1 defining a first surface 11 and a second surface 12 opposite to the first surface and several pairs of differential terminals 2. Each pair of differential terminals 2 consists of two terminals 21 transmitting a differential pair signal. Each terminal 21 include a contacting portion 211 for mating with a mating electrical connector, a leg portion 213 and a connecting portion 212 connecting the contacting portion and the contacting portion 211 and the leg portion 213. The leg portions 213 of the terminals are attached to the surfaces of the circuit board 1 in a horizontal form. The leg portions 213 can be mounted to the circuit board 1 by welding method, glue sticking, SMT, dip holes, for examples. As shown in FIGS. 6 and 7, a retaining block 3 is used on each surface of the circuit board to align the leg portions 213 of the terminals, the retaining blocks 3 can be locked with or positioned to the circuit board 1. The differential terminal pairs are respectively mounted to the first surface 11 and the second surface 12 of the circuit board 1, and each surface 11, 12 of the circuit board 1 are electrical connecting with at least one pair of differential terminals 2.

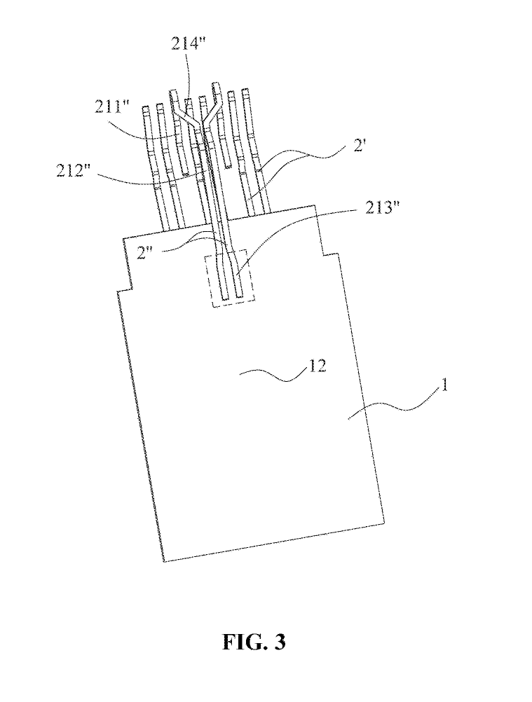

As shown in FIGS. 1 and 3, a first embodiment, the terminals, including a differential pair terminals, mounted on the first surface 11 are regarded as first different terminals 2′ and the terminals mounted on the second surface 12 is a second differential pair of terminals 2″. The first surface 11 disposes three pairs of terminals 2′ and at least one of them is a differential pair. The second surface 12 disposes one pair of terminal which is the second differential terminals 2″. Therefore, the circuit board 1 with four pairs of the terminals can be used in a RJ 45 connector which will be described hereinafter.

In other embodiments, each surface of the circuit board 1 can be disposed with two pairs of differential terminals, or each surface of the circuit board can be disposed with only one pair of differential terminals which is adapted for a RJ 11 connector (not shown).

Each of the paired terminals 2′ mounted on the first surface 11 of the circuit board includes a contacting portion 211′, a leg portions 213′ and a connecting portion 212′ joining the contacting portion 211′ and the leg portion 213′. The connecting portions 212′ extend forwards and slantwise away from the leg portions 213′ mounted on the first surface 11. Each of the second differential terminals 2″ includes a contacting portion 211″, a leg portions 213″, a connecting portion 212″ joining the contacting portion 211″ and the leg portion 213″ and a folded portion 214″. The connecting portions 212″ of the second pair differential terminals 2″ are extended forwardly and horizontally from the leg portions 213″, the folded portions 214″ are bent from the connecting portions 212″ and the contacting portions 211″ are cantilever arms which are extended from the folded portions 214″, respectively. Understandingly, the contacting portions 211′, 211″ of the first differential terminals 2′ and the second differential terminals 2″ extend toward different directions, so that electrical signal currents may flow along the contacting portions in differential directions, and it will decrease crosstalk produced by adjacent pairs of the contacting portions 211′, 211″ of the differential terminals.

The two differential terminals of each pair, in this embodiment, are formed in a mirroring setting to ensure the same electrical length of electric path. The contacting portions 211′, 211″ of the first and second differential terminals are arranged in a same row, the leg portions 213′ of the first differential terminals 2′ are mounted on the first surface 11 of the circuit board 1 while the leg portions 213″ of the second differential terminals 2″ are mounted on the second surface 12 of the circuit board 1. The connecting portions 212″ of each of the second differential terminals 2″ comprises a folded portion 214″ in front of the contacting portion 211″, which join the contacting portion 211″ and the connecting portion 212″ of the second differential terminals 2″.

The first differential terminals 2′ of the pair have a same distance wholly. The second differential terminals 2″ of the pair have a larger distance at the leg portion 213″ than that at the contacting portion 211″ as shown. The distance between two connecting portion 212″ of the second differential terminals are smaller than that of the first differential terminal 2′. Said arrangement can adjust signal impendence of adjacent pairs of the terminals.

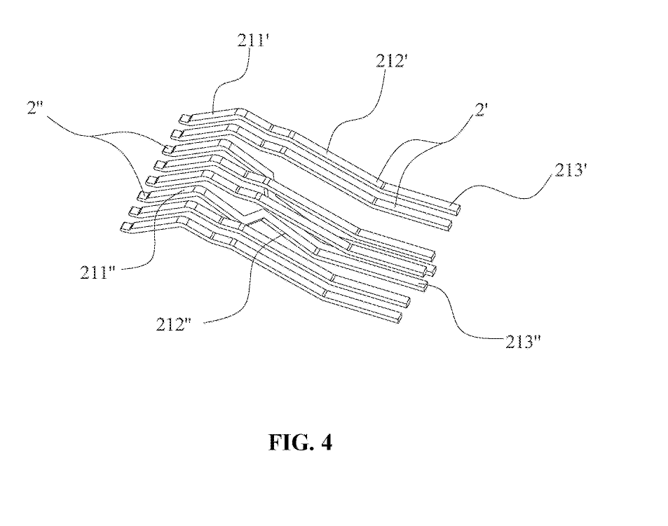

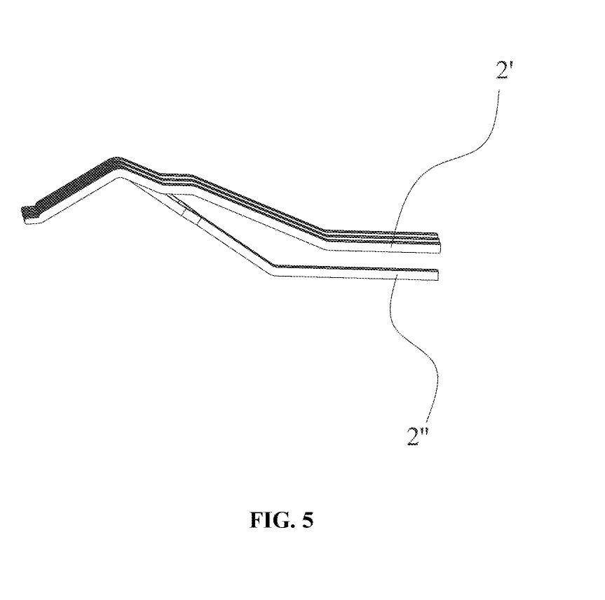

FIGS. 4 and 5 shown a second embodiment, the second differential terminals 2″ has no folded portion. The connecting portions 212″ are shaped in a zigzag form. However, that the leg portions 213″ of second differential terminals still can be mounted on the second surface 12 of the circuit board 1.

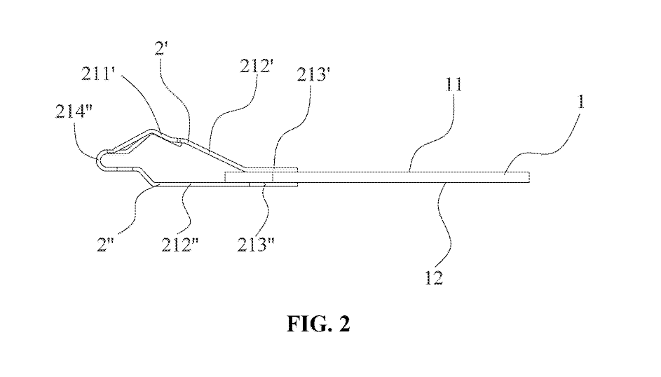

As best shown in FIG. 2, the connecting portions 212″ of the second differential terminals 2″ are flatly attached the second surface 12, thereby decrease impendence of the second differential terminals 2″. If possible, the connecting portion 212′ can also be configured to be flatly attached the first surface 11.

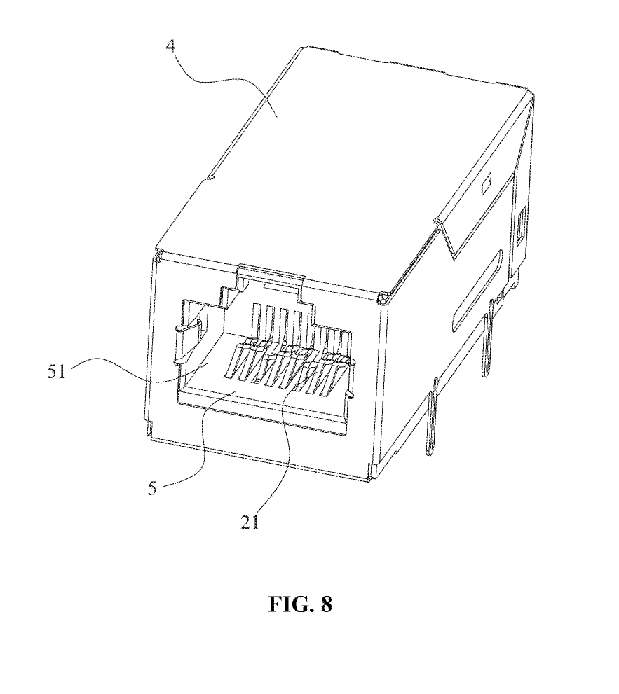

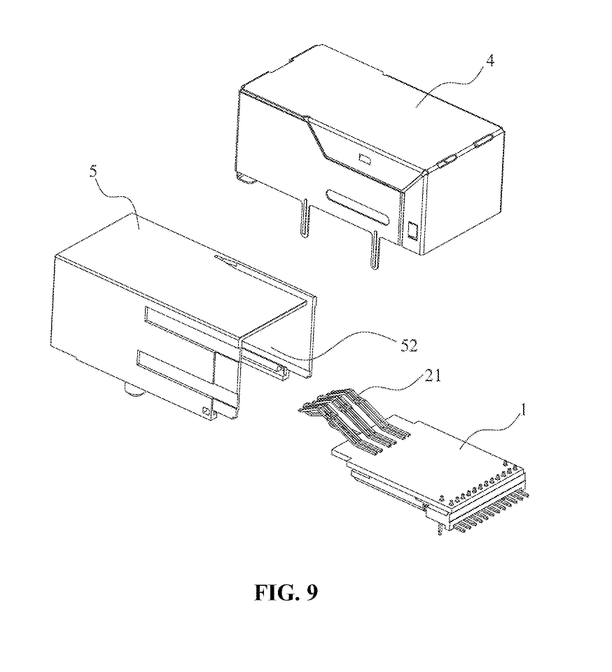

As shown in FIGS. 8 and 9, the circuit board 1 with the terminals 21 is assembled in a RJ 45 connector. The RJ 45 connector includes an insulating housing 5 defining a mating cavity 51, for receiving a RJ 45 plug (not shown), and a receiving cavity 52 and a shielding shell 4, surrounding the insulating housing 5. The contacting portions 211 of the terminals 21 are received in the insulating housing 5 and exposed to the mating cavity 51 and the circuit board 1 is received in the receiving cavity 52. Alternatively, the circuit board 1 with different numerals of the terminals can be used in RJ 11 connector and other similar connector. The differential pair terminals are distinctly arranged on opposite surface of the circuit board, to decease cross talk produced between different pairs of differential terminals.

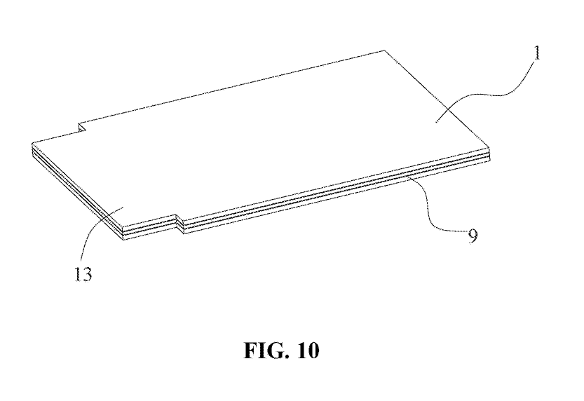

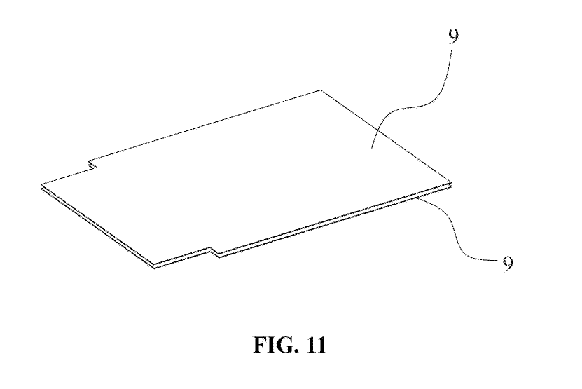

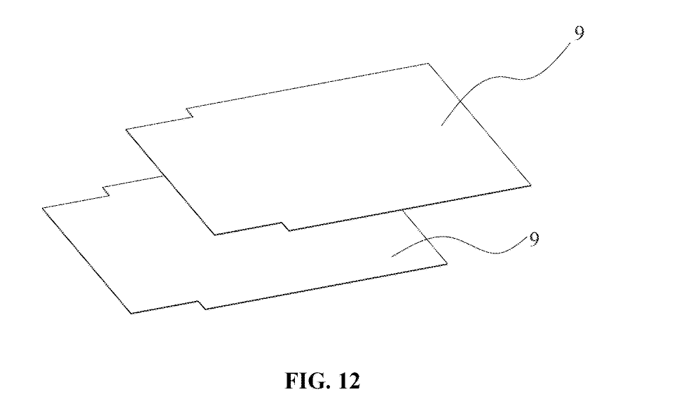

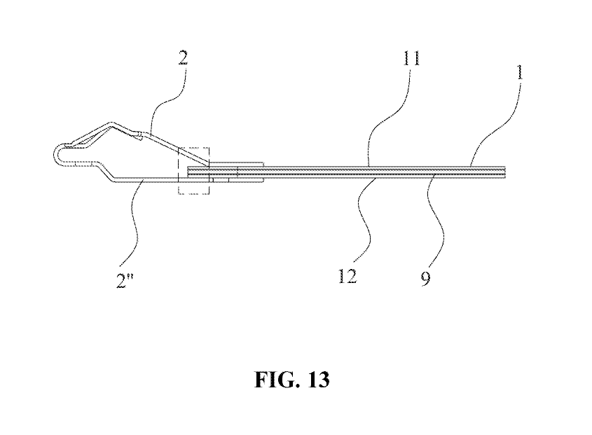

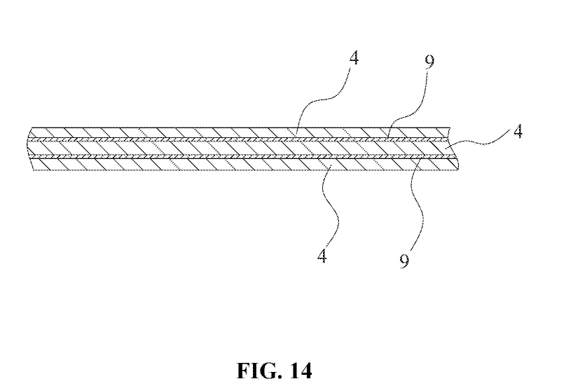

FIGS. 10 to 14 illustrating an improvement of the circuit board 1. The circuit board 1 comprises two substrates 4 and a shielding sheet 9 disposed between the two substrates 4. Each substrate 4 on the circuit board is a layer of electrical circuit disposed on a non-conductive material. The shielding sheet 9 is disposed between the first and second surface to electrical magnetically to isolate the differential terminals 2 on the circuit board 1, which is parallel to the first and second surface. The shielding sheet 9 is made from a metal sheet, such as a copper foil. Alternatively, if the circuit board 1 has three substrates 4, two shielding sheets 9 may applied, and each will be sandwiched between every two adjacent substrates. Please note, the shielding sheet 9 may extend along the whole circuit board even when the substrate has a protruding portion 13 as best shown in FIG. 10. The shielding sheet 9 benefits to decrease of the cross talk produced by the first and second pairs of the differential terminals.

It is to be understood, however, that even though numerous, characteristics and advantages of the present disclosure have been set forth in the foregoing description, together with details of the structure and function of the disclosure, the disclosed is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electrical connector comprising:
a circuit board defining a first surface and a second surface opposite to the first surface;
at least a pair of first differential terminals;
at least a pair of second differential terminals;
each terminal of the first and second differential terminals comprising a contacting portion for mating with a mating electrical connector, a leg portion and a connecting portion connecting with the contacting portion and the leg portion;
wherein the contacting portions of the first and the second differential terminals are arranged in the same row in a slant plane related to the circuit board, the leg portions of the first differential terminals are mounted on the first surface of the circuit board while the leg portions of the second differential terminals are mounted on the second surface of the circuit board.

2. The electrical connector as recited in claim 1, wherein the electrical connector further comprises two another pairs of first differential terminals with leg portions on the first surface of the circuit board.

3. The electrical connector as recited in claim 1, wherein the connecting portion of each of the second differential terminals comprises a folded portion in front of the contacting portion, which join the contacting portion and the connecting portion of the second differential terminals.

4. The electrical connector as recited in claim 1, wherein the second differential terminals of the pair has a larger distance at the leg portions thereof than that at the connecting portions thereof.

5. The electrical connector as recited in claim 4, wherein the second differential terminals of the pair has a larger distance at the contacting portions than that at the connecting portions.

6. The electrical connector as recited in claim 5, wherein the second differential terminals of the pair has a larger distance at the contacting portions than that at the leg portions.

7. The electrical connector as recited in claim 6, wherein at least one pair of the first differential terminals has the same distance therebetween.

8. The electrical connector as recited in claim 1, wherein the connecting portions of the first differential terminals extend forward and slantwise from the circuit board, while the connecting portions of the second differential terminals extend frontward and horizontally from the circuit board.

9. The electrical connector as recited in claim 8, wherein the second differential terminals comprises a folded portion jointing the connecting portions and the contacting portions, the contacting portions of the second differential terminal extend rearwards from the folded portion while the contacting portions of the first differential terminals extend forward.

10. The electrical connector as recited in claim 1, wherein the connecting portions of the first and the second differential terminals extend forward and slantwise from the circuit board.

11. The electrical connector as recited in claim 1, wherein the electrical connector comprises two insulating blocks locking the leg portions of the first differential terminals and the second differential terminals, respectively.

12. The electrical connector as recited in claim 1, wherein the circuit board comprises a shielding sheet disposed between the first and second surface to isolate the differential terminals.

13. The electrical connector as recited in claim 12, wherein the shielding sheet is parallel to the first and second surfaces of the circuit board.

14. The electrical connector as recited in claim 12, wherein the shielding sheet is made from a metal sheet.

15. The electrical connector as recited in claim 12, wherein the shielding sheet is a copper foil.

16. An electrical connector comprising:
an insulative housing defining a mating cavity opening for a complementary connector and a receiving cavity;
a circuit board received in the receiving cavity, and defining a first surface and a second surface opposite to the first surface;
pairs of differential terminals comprising contacting portions extending into the mating cavity and leg portions mounted on the circuit board;
wherein some leg portions of the pairs of differential terminals are mounted on the first surface of the circuit board and other leg portions are mounted on the second surface of the circuit board.

17. The electrical connector as recited in claim 16, wherein the circuit board comprises a metal sheet disposed between the first surface and the second surface thereof.

18. The electrical connector as recited in claim 17, wherein the metal sheet is a copper foil.

19. The electrical connector as recited in claim 16, wherein the contacting portions of the pairs of the differential terminals are arranged in a same row while extending in opposite directions.
